(19) United States
(12) Patent Application Publication
(10) Pub. No.: US 2020/0135519 A1
(43) Pub. Date: Apr. 30, 2020

(54) Shape-Distortion Standards for Calibrating Measurement Tools for Nominally Flat Objects

(71) Applicant: KLA Corporation, Milpitas, CA (US)

(72) Inventors: Farhat A. Quli, Castro Valley, CA (US); Winfred Chow, South San Francisco, CA (US)

(21) Appl. No.: 16/664,788

(22) Filed: Oct. 25, 2019

Related U.S. Application Data
(60) Provisional application No. 62/752,200, filed on Oct. 29, 2018.

(51) Int. Cl. H01L 21/67; H01L 21/66; G01B 11/30

(52) U.S. Cl. CPC H01L 21/67288; H01L 22/12; G01B 2210/56; G01B 11/306; H01L 22/20

(57) ABSTRACT

A first nominally flat object is obtained that has a controlled warpage that has been measured in a manner traceable through a standard reference material to a fundamental unit of measurement. A measurement tool is calibrated using the first nominally flat object. After calibrating the measurement tool using the first nominally flat object, the warpage of a plurality of nominally flat objects is measured using the measurement tool, wherein the plurality of nominally flat objects is distinct from the first nominally flat object.

### RELATED APPLICATION

This application claims priority to Patent Application No. 62/752,200, filed on Oct. 29, 2018, which is incorporated by reference in its entirety for all purposes.

### TECHNICAL FIELD

This disclosure relates to measuring the shape (warpage or bowing) of nominally flat objects, and more specifically to fabricating and characterizing a reference object used to calibrate measurement tools that measure the shape of nominally flat objects (e.g., semiconductor wafers).

### BACKGROUND

Specialized measurement tools allow measurement of the shape (warpage or bowing) of nominally flat objects. For the measurements that such tools provide to be accurate, the tools must be properly calibrated. Such tools may be calibrated using step-height standards or optical flats. For example, an optical flat may be built into a measurement tool, for use as a reference. Such calibration techniques have been found to result sometimes in non-reproducible measurements, however, raising questions about their accuracy. Furthermore, the shape of the object being used for calibration does not match the shape of the objects (e.g., semiconductor wafers) being measured with the calibrated measurement tool, raising further concerns about measurement accuracy.

Shape measurement has become a topic of increasing importance in semiconductor manufacturing. For example, warping (or bowing) of some types of semiconductor wafers (e.g., wafers with three-dimensional (3D) memory devices, such as 3D flash memories, fabricated on them) has increased as the number of film layers deposited on them has increased. Semiconductor manufacturers wish to accurately characterize such warpage.

### SUMMARY

Accordingly, there is a need for improved methods and systems for calibrating and characterizing measurement tools used to measure the shape (e.g., warpage) of nominally flat objects.

In some embodiments, a method is performed in which a first nominally flat object is obtained that has a controlled warpage that has been measured in a manner traceable through a standard reference material to a fundamental unit of measurement. A measurement tool is calibrated using the first nominally flat object. After calibrating the measurement tool using the first nominally flat object, the warpage of a plurality of nominally flat objects is measured using the measurement tool, wherein the plurality of nominally flat objects is distinct from the first nominally flat object.

In some embodiments, an inspection system includes a measurement tool for measuring warpage of nominally flat objects, one or more processors, and memory storing one or more programs for execution by the one or more processors. The one or more programs include instructions for calibrating a measurement tool using a first nominally flat object having a controlled warpage that has been measured in a manner traceable through a standard reference material to a fundamental unit of measurement. The one or more programs also include instructions for, after calibrating the measurement tool using the first nominally flat object, measuring the warpage of a plurality of nominally flat objects using the measurement tool, wherein the plurality of nominally flat objects is distinct from the first nominally flat object.

In some embodiments, a method is performed in which a nominally flat object with a controlled warpage is fabricated. A measurement of the warpage of the nominally flat object is made. The measurement is traceable through a standard reference material to a fundamental unit of measurement. The nominally flat object is provided as a reference object for calibrating a measurement tool.

### BRIEF DESCRIPTION OF THE DRAWINGS

For a better understanding of the various described implementations, reference should be made to the Detailed Description below, in conjunction with the following drawings.

FIG. 1 is a flowchart showing a method of producing a reference object that may be used to calibrate a measurement tool, in accordance with some embodiments.

FIG. 2 is a flowchart showing a method of operating a measurement tool to measure warpage, in accordance with some embodiments.

FIG. 3 is a cross-sectional view of a nominally flat object that has a controlled warpage in accordance with some embodiments.

FIGS. 4A and 4B are cross-sectional views illustrating fabrication of a nominally flat silicon wafer with a controlled warpage through oxide growth and etching in accordance with some embodiments.

FIGS. 5A-5C are cross-sectional views illustrating fabrication of a nominally flat silicon wafer with a controlled warpage through bonding a substrate to the nominally flat object while heated, in accordance with some embodiments.

FIG. 6 is a cross-sectional view illustrating a technique for measuring the warpage of a nominally flat object by shining light through an optical flat onto the bottom side of the nominally flat object and measuring a resulting phase shift, in accordance with some embodiments.

FIGS. 7A and 7B are respective cross-sectional and plan views illustrating the use of non-contact probes to measure warpage of a nominally flat object in accordance with some embodiments.

FIG. 8 is a block diagram of an inspection system for measuring warpage in accordance with some embodiments.

Like reference numerals refer to corresponding parts throughout the drawings and specification.

### DETAILED DESCRIPTION

Reference will now be made in detail to various embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

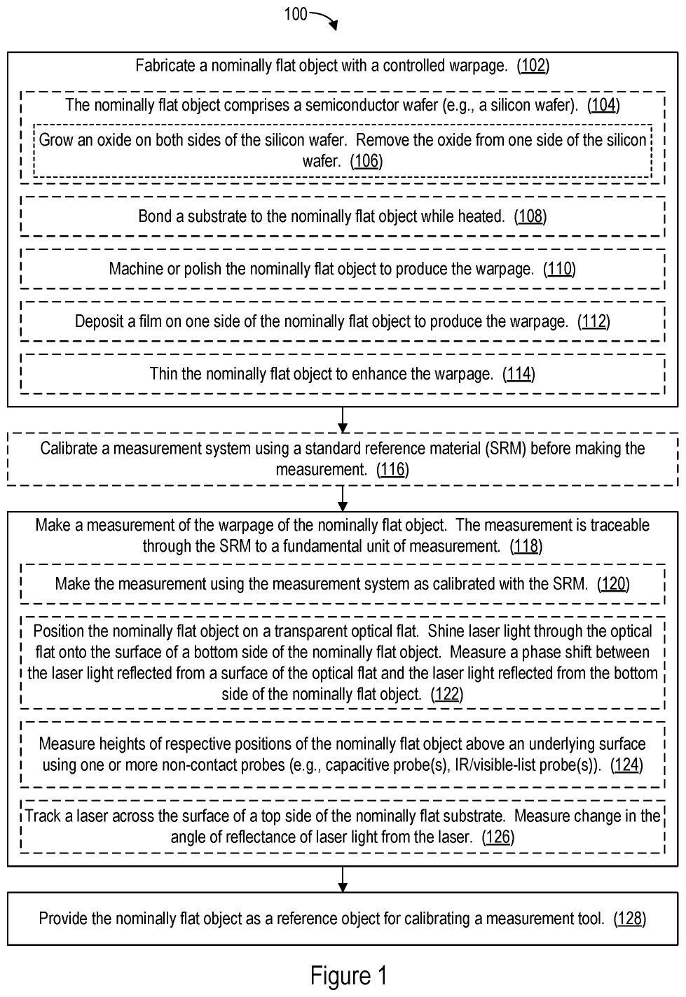

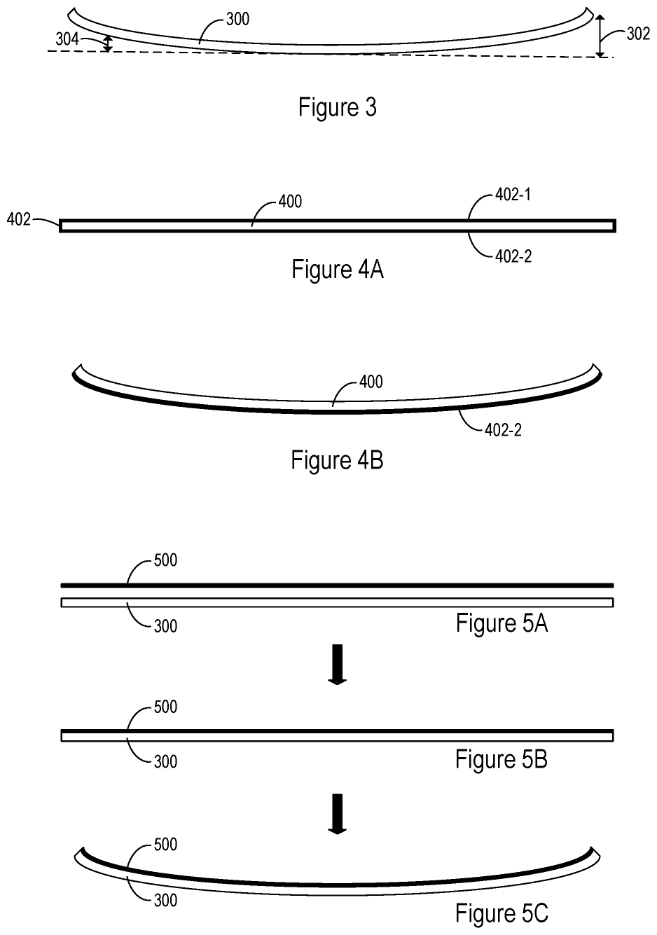

FIG. 1 is a flowchart showing a method 100 of producing a reference object that may be used to calibrate a measurement tool, in accordance with some embodiments. In the method 100, a nominally flat object 300 (FIG. 3) that has a controlled warpage is fabricated (102). (FIG. 3 and subsequent figures showing cross-sectional views of warpage are not to scale; the warpage is exaggerated.) The nominally flat object 300 has a total warpage 302 measured from the height of the lowest point on the bottom surface to the height of the highest point on the bottom surface (e.g., from the center height to the edge height) with the nominally flat object 300 resting on a flat support (e.g., an optical flat or wafer chuck). In some embodiments, the total warpage 302 is 1 mm or less. A local warpage 304 may be determined for respective points on the nominally flat object 300. The warpage (e.g., the total warpage 302 and/or local warpage 304 at one or more points) is controlled in that it is approximately reproducible. For example, the nominally flat object 300 is fabricated to have a warpage that matches a specified value (e.g., of 1 mm or less), to within manufacturing tolerances.

In some embodiments, the nominally flat object 300 is (104) a semiconductor wafer (e.g., a silicon wafer 400, FIGS. 4A-4B). For example, fabricating the nominally flat object 300 includes growing (106) an oxide 402 (FIG. 4A) on both sides of the silicon wafer 400, including an oxide layer 402-1 on the top surface (i.e., top side) of the silicon wafer 400 and an oxide layer 402-2 on the bottom surface (i.e., bottom side) of the silicon wafer 400, and removing the oxide 402 from one side of the silicon wafer 400 (e.g., removing the oxide layer 402-1 from the top surface, resulting in the structure shown in FIG. 4B). The oxide 402 (e.g., the oxide layer 402-1, FIG. 4A) may be removed from one side of the silicon wafer 400 by etching it away. The oxide 402 on the other side of the silicon wafer 400 (e.g., the oxide layer 402-2, FIG. 4B) is left on the silicon wafer 400 and may be considered part of the nominally flat object 300 in accordance with some embodiments.

In some embodiments, fabricating the nominally flat object 300 includes bonding (108) a substrate 500 to the nominally flat object 300 while heated, as shown in FIGS. 5A-5C. The substrate 500 and the nominally flat object 300 have different coefficients of thermal expansion (e.g., the substrate 500 has a higher coefficient of thermal expansion than the nominally flat object 300). For example, the nominally flat object 300 is a semiconductor wafer (e.g., a silicon wafer) and the substrate 500 is metal (e.g., aluminum). The substrate 500 and the nominally flat object 300 are heated (e.g., to the same temperature) and, while heated, are bonded together, as shown in FIG. 5B. After bonding, the substrate 500 and the nominally flat object 300 are cooled (e.g., to ambient temperature). The difference between the coefficients of thermal expansion causes warpage when the bonded substrate 500 and nominally flat object 300 cool, as shown in FIG. 5C. The substrate 500 is left bonded to the nominally flat object 300 and may be considered part of the nominally flat object 300 in accordance with some embodiments.

In some embodiments, the nominally flat object 300 is machined or polished (110) to produce the warpage.

In some embodiments, one or more films are deposited (112) on one side of the nominally flat object 300. For example, metal(s), insulator(s), and/or semiconductor(s) are deposited on the nominally flat object 300 using physical vapor deposition (PVD), chemical vapor deposition (CVD), spin-on deposition, or other deposition technique(s). The one or more films induce stress in the nominally flat object 300 that causes the warpage. The one or more films are left on the nominally flat object 300 and may be considered part of the nominally flat object 300 in accordance with some embodiments.

In some embodiments, the nominally flat object 300 is thinned (114) to enhance the warpage. For example, thinning the top side of the silicon wafer 400 (i.e., the side from which the oxide layer 402-1 has been removed) enhances the warpage shown in FIG. 4B. This thinning may be performed in conjunction with various techniques for inducing the warpage (e.g., in conjunction with any of steps 106-112).

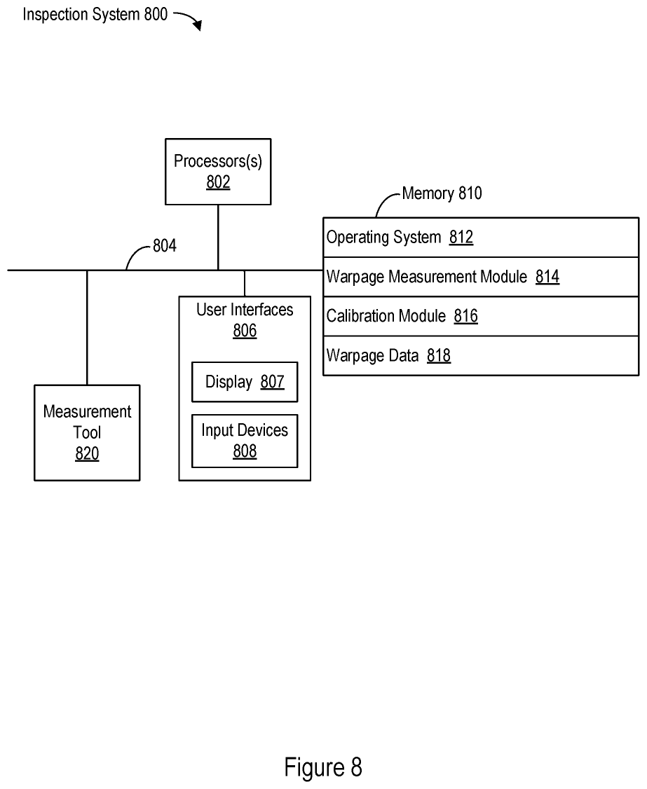

In some embodiments, a measurement system (e.g., an inspection system 800, FIG. 8) is calibrated (116) using a standard reference material (SRM) before making the measurement. An SRM as the term is used herein is a reference object with one or more dimensions that have known values and uncertainty, as measured and certified by a standards body such as the United States National Institute of Standards and Technology (NIST) or an equivalent institute in another country. The standards body performs the measurement in a manner that is traceable to a fundamental unit of measurement (e.g., the meter). The standards body may produce and provide (e.g., sell) the reference object, or the reference object may be provided to the standards body for measurement and certification. An SRM as described herein is assumed to have already been measured and certified by the standards body.

A measurement of the warpage of the nominally flat object 300 is made (118). The measurement is traceable through the SRM to the fundamental unit of measurement. For example, the measurement is made (120) using the measurement system as calibrated with the SRM.

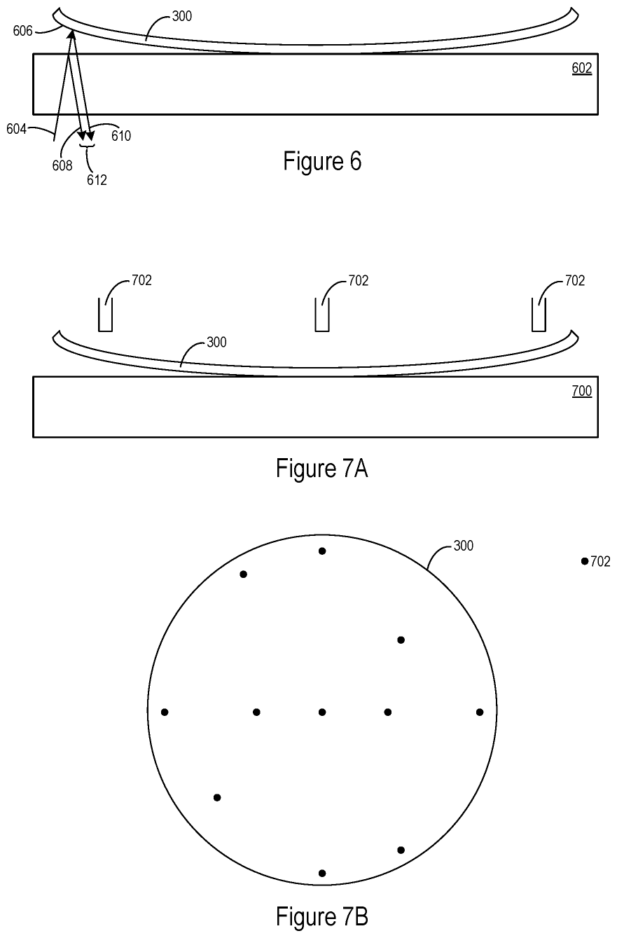

In some embodiments, making this measurement includes positioning (122) the nominally flat object 300 on a transparent optical flat 602 (FIG. 6) and shining laser light 604 through the optical flat onto the surface of a bottom side 606 of the nominally flat object 300 (i.e., onto the bottom surface, which faces the optical flat 602). A phase shift 612 between the laser light 608 reflected from a surface of the optical flat 602 and the laser light 610 reflected from the bottom side 606 of the nominally flat object 300 is measured. For example, the phase shift is determined by measuring interference fringes caused by interference between the laser light 608 and the laser light 610. Shining the laser light 604 and measuring the phase shift 612 may be performed at multiple locations on the nominally flat object (e.g., multiple positions on the bottom side 606). Making the measurement may further include measuring the thickness of the nominally flat object 300 at the multiple locations.

In some embodiments, heights of respective positions on the nominally flat object 300 (e.g., on the top side of the nominally flat object 300) above an underlying surface 700 are measured (124) using one or more non-contact probes 702, as shown in FIGS. 7A-7B. For example, the heights are measured using one or more capacitive proves, one or more infrared (IR) probes, and/or one or more visible-light probes that do not contact the top surface (i.e., the surface of the top side) of the nominally flat object 300, as shown in FIG. 7A. The non-contact probes 702 may be positioned at positions above the nominally flat object 300, as shown in the example of FIG. 7B, in which the nominally flat object 300 is a semiconductor wafer. The positions may vary between embodiments. The positions may be adjustable, such that a single non-contract probe 702 may be used to make measurements at multiple positions, or may be fixed.

In some embodiments, a laser (e.g., which may be an example of a non-contact probe 702, FIG. 7A) is tracked (126) across the surface of a top side of the nominally flat object 300, with light from the laser being shone on the nominally flat object 300 accordingly. The nominally flat object reflects the laser light. While tracking the laser across the surface, change in the angle of reflectance of the laser light is measured. This change indicates the curvature of the surface, and thus measures the warpage.

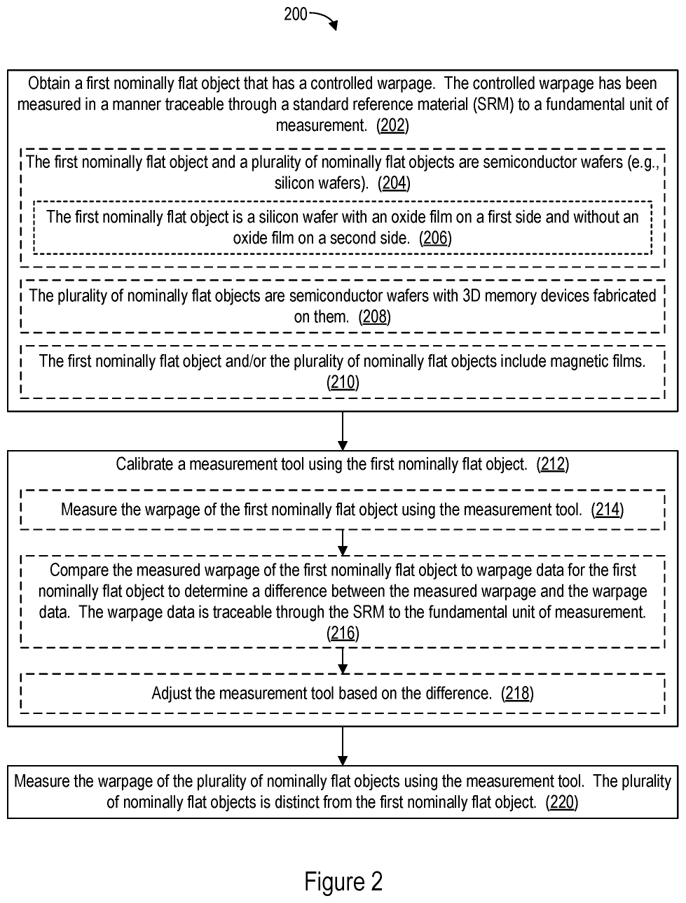

The nominally flat object 300 is provided (128) as a reference object for calibrating one or more measurement tools, along with warpage data from the measurement of step 118. For example, the nominally flat object 300 and warpage data are provided to a factory (e.g., a wafer fab) that fabricates objects (e.g., semiconductor wafers) having a similar shape to the nominally flat object 300. The factory may use the nominally flat object to calibrate its inspection systems (e.g., inspections systems 800, FIG. 8) that measure warpage. An example of such calibration is described below for step 212 of the method 200 (FIG. 2).

FIG. 2 is a flowchart showing a method 200 of operating a measurement tool (e.g., the measurement tool 820 in an inspection system 800, FIG. 8) to measure warpage in accordance with some embodiments. In the method 200, a first nominally flat object that has a controlled warpage (e.g., the nominally flat object 300, FIG. 3, as produced in the method 100, FIG. 1) is obtained (202). The controlled warpage has been measured in a manner traceable through an SRM to a fundamental unit of measurement (e.g., as in the step 118 of the method 100, FIG. 1). In some embodiments, the first nominally flat object and a plurality of nominally flat objects are (204) semiconductor wafers (e.g., silicon wafers). For example, the first nominally flat object is (206) a silicon wafer 400 with an oxide film 402-2 (FIG. 4B) on a first side and without an oxide film on a second side. In some embodiments, the plurality of nominally flat objects is (208) a plurality of semiconductor wafers (e.g., silicon wafers) with semiconductor devices (e.g., 3D memory devices, such as 3D flash memory devices) fabricated on them; the semiconductor wafers have warpage that results at least in part from film layers deposited on each semiconductor wafer to form the semiconductor devices.

Other examples of nominally flat objects besides semiconductor wafers are possible. For example, the first nominally flat object and/or the plurality of nominally flat objects may include magnetic films on substrates (210) (e.g., for disk-drive heads), reticles, or glass substrates with films deposited on them.

A measurement tool (e.g., the measurement tool 820, FIG. 8) is calibrated (212) using the first nominally flat object. In some embodiments, the warpage of the first nominally flat object is measured (214) using the measurement tool. The measured warpage of the first nominally flat object is compared (216) to warpage data for the first nominally flat object to determine a difference between the measured warpage and the warpage data. The warpage data is traceable through the SRM to the fundamental unit of measurement. The measurement tool is adjusted (218) based on the difference. Steps 214, 216, and 218 may be repeated during the calibration (e.g., until convergence occurs such that the measured warpage matches the warpage data).

After calibrating the measurement tool using the first nominally flat object, the warpage of the plurality of nominally flat objects is measured (220) using the measurement tool. The plurality of nominally flat objects is distinct from the first nominally flat object. These measurements are performed while the measurement tool is still in calibration. The measurement tool may be re-calibrated from time to time (e.g., periodically, or after a specified number of measurements have been made). For example, the plurality of the nominally flat objects may include multiple groups of the nominally flat objects, and the method 200 may further include re-calibrating the measurement tool using the first nominally flat object (i.e., repeating step 212) after measuring the warpage of each group of the nominally flat objects.

In some embodiments, the measurement tool used in steps 212 and 220 (e.g., the measurement tool 820, FIG. 8) is an interferometric measurement tool; calibrating the measurement tool and measuring the shape of the plurality of nominally flat objects include performing interferometry. Alternatively, the measurement tool may use another measurement technique (e.g., a technique used in step 118 of the method 100, FIG. 1, such as the technique shown in FIG. 6 or FIGS. 7A-7B).

FIG. 8 is a block diagram of an inspection system 800 for measuring warpage in accordance with some embodiments. The semiconductor-inspection system 800 may be an example of the measurement system of the method 100 (FIG. 1) or of an inspection system that includes the measurement tool of the method 200 (FIG. 2). The semiconductor-inspection system 800 includes a measurement tool 820 and a computer system with one or more processors 802 (e.g., CPUs), user interfaces 806, memory 810, and communication bus(ses) 804 interconnecting these components. This computer system may be integrated into the measurement tool 820. In some embodiments, the semiconductor-inspection system 800 includes multiple measurement tools 820. The computer system may further include one or more network interfaces (wired and/or wireless, not shown) for communicating with remote computer systems.

The user interfaces 810 may include a display 807 and one or more input devices 808 (e.g., a keyboard, mouse, touch-sensitive surface of the display 807, etc.). The display 807 may display results of calibrating the measurement tool 820 (e.g., in step 116, FIG. 1 or step 212, FIG. 2) and/or results of measurements made using the measurement tool 820 (e.g., in step 118, FIG. 1, or step 220, FIG. 2).

Memory 810 includes volatile and/or non-volatile memory. Memory 810 (e.g., the non-volatile memory within memory 810) includes a non-transitory computer-readable storage medium. Memory 810 optionally includes one or more storage devices remotely located from the processors 802 and/or a non-transitory computer-readable storage medium that is removably inserted into the system 800. In some embodiments, memory 810 (e.g., the non-transitory computer-readable storage medium of memory 810) stores the following modules and data, or a subset or superset thereof: an operating system 812 that includes procedures for handling various basic system services and for performing hardware-dependent tasks, a warpage measurement module 814 for causing the measurement tool 820 to make warpage measurements, a calibration module 816 for calibrating the measurement tool 820, and warpage data 818. The warpage data 818 may include the warpage data of step 216 of the method 200 (FIG. 2) (e.g., the results of the measurement of step 118 of the method 100, FIG. 1) and/or warpage data resulting from measurements made in step 220 of the method 200 (FIG. 2).

Each of the modules stored in the memory 810 corresponds to a set of instructions for performing one or more functions described herein. The memory 810 (e.g., the non-transitory computer-readable storage medium of the memory 810) includes instructions for performing portions of the method 100 (FIG. 1) and/or the method 200 (FIG. 2). For example, the memory 810 includes instructions for performing steps 116 and 118 of the method 100 (FIG. 1) and/or of performing steps 212-220 of the method 200 (FIG. 2). Separate modules need not be implemented as separate software programs. The modules and various subsets of the modules may be combined or otherwise re-arranged. In some embodiments, the memory 810 stores a subset or superset of the modules and/or data identified above.

FIG. 8 is intended more as a functional description of various features that may be present in an inspection system than as a structural schematic. For example, the functionality of the computer system in the inspection system 800 may be split between multiple devices. A portion of the modules stored in the memory 810 may alternatively be stored in one or more other computer systems communicatively coupled with the computer system of the inspection system 800 through one or more networks.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. A method, comprising:
fabricating a nominally flat object with a controlled warpage;
making a measurement of the warpage of the nominally flat object, the measurement being traceable through a standard reference material to a fundamental unit of measurement; and
providing the nominally flat object as a reference object for calibrating a measurement tool.

2. The method of claim 1, wherein:
making the measurement is performed using a measurement system; and
the method further comprises calibrating the measurement system using the standard reference material before making the measurement.

3. The method of claim 1, wherein the nominally flat object comprises a semiconductor wafer.

4. The method of claim 3, wherein the semiconductor wafer is a silicon wafer.

5. The method of claim 4, wherein fabricating the nominally flat object comprises:
growing an oxide on both sides of the silicon wafer; and
removing the oxide from one side of the silicon wafer.

6. The method of claim 1, wherein fabricating the nominally flat object comprises:
heating the nominally flat object and a substrate, wherein the substrate and the nominally flat object have different coefficients of thermal expansion;
with the nominally flat object heated and the substrate heated, bonding a substrate to the nominally flat object; and
after bonding the substrate to the nominally flat object, cooling the substrate and the nominally flat object.

7. The method of claim 1, wherein fabricating the nominally flat object comprises machining or polishing the nominally flat object to produce the warpage.

8. The method of claim 1, wherein fabricating the nominally flat object comprises depositing a film on one side of the nominally flat object, wherein the film induces stress in the nominally flat object to cause the warpage.

9. The method of claim 1, wherein fabricating the nominally flat object comprises thinning the nominally flat object to enhance the warpage.

10. The method of claim 1, wherein making the measurement comprises:
positioning the nominally flat object on a transparent optical flat;
shining laser light through the optical flat onto the surface of a bottom side of the nominally flat object; and
measuring a phase shift between the laser light reflected from a surface of the optical flat and the laser light reflected from the bottom side of the nominally flat object.

11. The method of claim 10, wherein:
shining the laser light and measuring the phase shift are performed at multiple locations on the nominally flat object; and
making the measurement further comprises measuring the thickness of the nominally flat object at the multiple locations.

12. The method of claim 1, wherein making the measurement comprises measuring heights of respective positions of the nominally flat object above an underlying surface using one or more non-contact probes.

13. The method of claim 12, wherein the one or more non-contact probes are selected from the group consisting of one or more capacitive probes, one or more infrared probes, and one or more visible-light probes.

14. The method of claim 1, wherein making the measurement comprises:
tracking a laser across the surface of a top side of the nominally flat object; and
while tracking the laser across the surface, measuring change in an angle of reflectance of laser light from the laser, the laser light being reflected by the nominally flat object.

15. A method, comprising:
obtaining a first nominally flat object having a controlled warpage that has been measured in a manner traceable through a standard reference material to a fundamental unit of measurement;
calibrating a measurement tool using the first nominally flat object; and
after calibrating the measurement tool using the first nominally flat object, measuring the warpage of a plurality of nominally flat objects using the measurement tool, wherein the plurality of nominally flat objects is distinct from the first nominally flat object.

16. The method of claim 15, wherein the first nominally flat object and the plurality of nominally flat objects comprise semiconductor wafers.

17. The method of claim 15, wherein the semiconductor wafers are silicon wafers.

18. The method of claim 15, wherein the first nominally flat object is a silicon wafer with an oxide film on a first side and without an oxide film on a second side.

19. The method of claim 15, wherein the plurality of nominally flat objects is semiconductor wafers with semiconductor devices fabricated on them, the warpage of the plurality of nominally flat objects resulting at least in part from film layers deposited on each semiconductor wafer to form the semiconductor devices.

20. The method of claim 15, wherein calibrating the measurement tool using the first nominally flat object comprises:
measuring the warpage of the first nominally flat object using the measurement tool;
comparing the measured warpage of the first nominally flat object to warpage data for the first nominally flat object to determine a difference between the measured warpage and the warpage data, the warpage data being traceable through the standard reference material to the fundamental unit of measurement; and
adjusting the measurement tool based on the difference.

21. The method of claim 15, wherein:
the plurality of the nominally flat objects comprises multiple groups of the nominally flat objects; and
the method further comprises re-calibrating the measurement tool using the first nominally flat object after measuring the warpage of each group of the nominally flat objects.

22. The method of claim 15, wherein:
the measurement tool is an interferometric measurement tool; and
calibrating the measurement tool and measuring the shape of the plurality of nominally flat objects comprise performing interferometry.

23. An inspection system, comprising:
a measurement tool for measuring warpage of nominally flat objects;
one or more processors; and
memory storing one or more programs for execution by the one or more processors, the one or more programs comprising instructions for:
calibrating a measurement tool using a first nominally flat object having a controlled warpage that has been measured in a manner traceable through a standard reference material to a fundamental unit of measurement; and
after calibrating the measurement tool using the first nominally flat object, measuring the warpage of a plurality of nominally flat objects using the measurement tool, wherein the plurality of nominally flat objects is distinct from the first nominally flat object.
